(19) United States
(12) Patent Application Publication
(10) Pub. No.: US 2004/0125568 A1
(43) Pub. Date: Jul. 1, 2004

(54) Thermal enhance package and manufacturing method thereof

(75) Inventor: Su Tao, Kaohsiung (TW)

Correspondence Address: BACON & THOMAS, PLLC, 625 SLATERS LANE, FOURTH FLOOR, ALEXANDRIA, VA, 22314

(73) Assignee: Advanced Semiconductor Engineering, Inc., Kaoshiung (TW)

(21) Appl. No.: 10/664,877

(22) Filed: Sep. 22, 2003

(30) Foreign Application Priority Data
Dec. 30, 2002 (TW) 091137930

(51) Int. Cl. H05K 7/20

(52) U.S. Cl. 361/707

(57) ABSTRACT

A thermal enhance package mainly comprises a chip, a substrate unit, a heat spreader unit and a plurality of pellets. The chip is disposed above the substrate unit and electrically connected to the substrate unit, and an encapsulation unit encapsulates the chip, the substrate unit, the heat spreader unit and the pellets. Therein the pellets are formed on the substrate unit and connect the substrate unit and the heat spreader unit. Thus the heat arisen out of the chip can be transmitted to the heat spreader unit not only through the encapsulation unit but also the pellets. Moreover, the substrate unit has at least one grounding contact connecting to one of the pellets so as to provide the thermal enhance package a good shielding. In addition, a method for manufacturing the thermal enhance package is also provided.

### BACKGROUND OF THE INVENTION

1. Field of Invention

This invention relates to a thermal enhance package. More particularly, the present invention is related to a thermal enhance ball grid array package and a manufacturing method thereof.

2. Related Art

Integrated circuit (chip) packaging technology is becoming a limiting factor for the development in packaged integrated circuits of higher performance. Semiconductor package designers are struggling to keep pace with the increase in pin count, size limitations, low profile, and other evolving requirements for packaging and mounting integrated circuits. Nowadays, ball grid array package (BGA) and chip scale package (CSP) are wildly applied to chip package with high I/Os and assembly package for thermal enhance integrated circuits.

Originally, as shown in FIGS. 1, 2 and 3, a conventional manufacturing method of ball grid array package comprises the following steps. First, referring to FIG. 1, a substrate including a plurality of substrate units 11 is provided and arranged in the form of a matrix. Each substrate unit has a die paddle 112 and a plurality of contacts 114 surrounding the die paddle 112. Next, referring to FIG. 2, a plurality of chips 21 are provided, and each of the chips is attached onto the corresponding die paddle 112 of each of the substrate units 11 via an adhesive, for example a silver glue. Then the adhesive is cured to connect the chip 21 and the die paddle 112 securely. Afterwards, the conductive wires 23, for example gold wires, connect the chip 21 and the substrate unit 11. Furthermore, a matrix molding process is performed to encapsulate the substrate units 11, the chips 21 and the conductive wires 23 by an encapsulation 24 and a plurality of marks are formed by ink marking or laser marking on the top surface of the encapsulation. Finally, a process of post cure is performed and a singulation process is performed to form a plurality of semiconductor packages as shown in FIG. 3.

When the chip is operated, more and more heat will be produced. Accordingly, in order to enhance the thermal performance of the semiconductor package, originally a heat spreader is attached on the top surface of the encapsulation (not shown). Alternately, referring to FIGS. 4A and 4B, a heat spreader 3 having a plurality of heat spreader units 31 is attached onto the mold chase 4 before the encapsulating process is performed. Therein each heat spreader unit 31 is attached to the corresponding chip 21. When the encapsulating process is performed and the process of post cure is performed in the sequence of the performing of the encapsulating process, the encapsulation 24 exposes each heat spreader unit 31 as shown in FIG. 5. Finally, the heat spreader 3, the substrate 1 and the encapsulation are singulated simultaneously to form a plurality of semiconductor packages wherein each semiconductor package has a heat spreader unit 31 formed on an encapsulation unit 241 as shown in FIG. 6.

However, there are some disadvantages in the above-mentioned ball grid array semiconductor package. For example, the heat spreader unit 31 is not connected to the grounding contacts of the substrate unit 11 so as not to provide the package a good shielding. Accordingly, it also can't provide great electrical performance for an assembly package having a device with high-frequency circuits. Besides, as shown in FIG. 6, the heat arisen out of the chip 21 will be transmitted to the heat spreader unit 31 through the encapsulation unit 241 so as to lower the thermal performance of the assembly package. Moreover, as shown in FIG. 4A, the area of the heat spreader 3 is large and only two supports at the edges. Thus the heat spreader 3 is easily deformed caused by the weight of the heat spreader 3 so as to lower the yield of the semiconductor package.

Therefore, providing another thermal enhance package and a manufacturing method thereof to solve the mentioned-above disadvantages is the most important task in this invention.

### SUMMARY OF THE INVENTION

In view of the above-mentioned problems, an objective of this invention is to provide a thermal enhance package and a manufacturing method thereof to upgrade the thermal performance of the package and provide a good shielding to enhance the electrical performance of the package.

To achieve the above-mentioned objective, a thermal enhance package is provided, wherein the package mainly comprises a chip, a substrate unit, a heat spreader unit and a plurality of pellets. Therein the substrate unit has an upper surface and a lower surface; the chip is disposed on the upper surface of the substrate unit and electrically connected to the substrate unit; the heat spreader unit is disposed above the chip; and the pellets are disposed on the upper surface of the substrate unit and connected to the heat spreader unit. Accordingly, the heat arisen out of the chip can be easily transmitted to the outside through the pellets. Besides, a solder mask layer is formed on the upper surface of the substrate unit so as to expose at least a grounding contact for connecting to one of the pellets. Thus a good shielding will be provided and the electrical performance of the package will be enhanced.

In addition, this invention also provides a manufacturing method of the thermal enhance package. The method mainly comprises providing a substrate in the form of a matrix having a plurality of substrate units, forming a plurality of pellets on the upper surface of each substrate unit of the substrate, electrically connecting the active surface of each chip to each substrate unit, providing a heat spreader having a plurality of heat spreader units to connect to the pellets and the chips simultaneously, encapsulating the chips, the substrate units, the heat spreader units and the pellets to form an encapsulation in the form of a matrix having a plurality of encapsulation units, and singulating the encapsulation to from a plurality of thermal enhance packages.

As mentioned above, the pellets connect the heat spreader units and the substrate units so as to upgrade the thermal performance and the electrical performance of the package by providing another heat transmission paths and providing a good shielding.

### BRIEF DESCRIPTION OF THE DRAWINGS

The invention will become more fully understood from the detailed description given herein below illustrations only, and thus are not limitative of the present invention, and wherein:

FIGS. 1 to 3 are cross-sectional views illustrating the process flow of a manufacturing method of a conventional ball grid array semiconductor package;

FIGS. 4A, 5 and 6 are cross-sectional views illustrating the process flow of a manufacturing method of a conventional ball grid array semiconductor package with a heat spreader;

FIG. 4B is a cross-sectional view of the heat spreader of FIG. 4A;

FIG. 7A is a cross-sectional view of a thermal enhance package according to the first embodiment of the present invention;

FIG. 7B is a cross-sectional view of a thermal enhance package according to the second embodiment of the present invention;

FIG. 8A is a cross-sectional view of a thermal enhance package according to the third embodiment of the present invention;

FIG. 8B is a cross-sectional view of a thermal enhance package according to the fourth embodiment of the present invention;

FIG. 9 is a flow chart illustrating the process flow of the manufacturing method of the thermal enhance package of FIGS. 7A and 7B; and

FIGS. 10A, 10B, 10C, and 11 to 14 are cross-sectional views illustrating the process flow of the manufacturing method of the thermal enhance package of FIG. 7A.

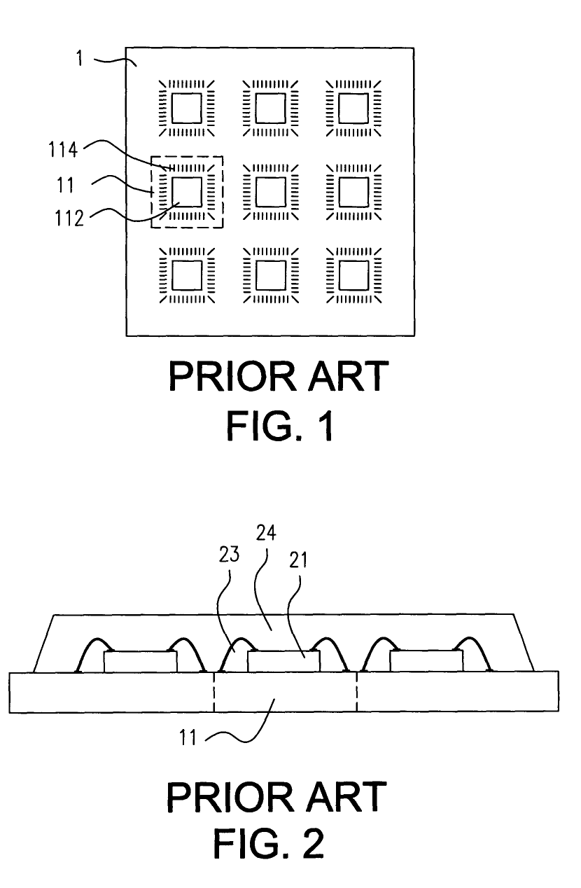

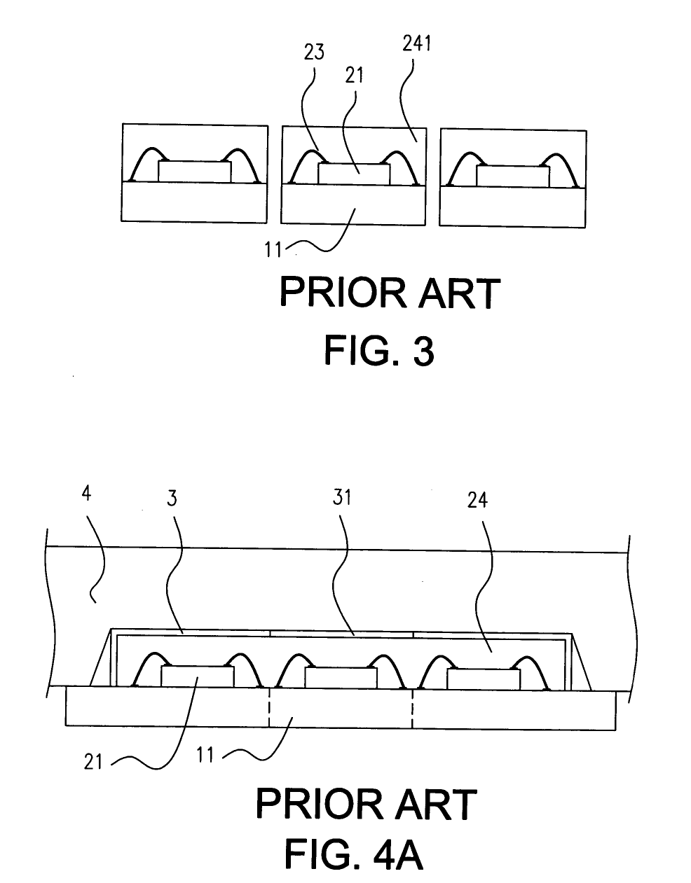

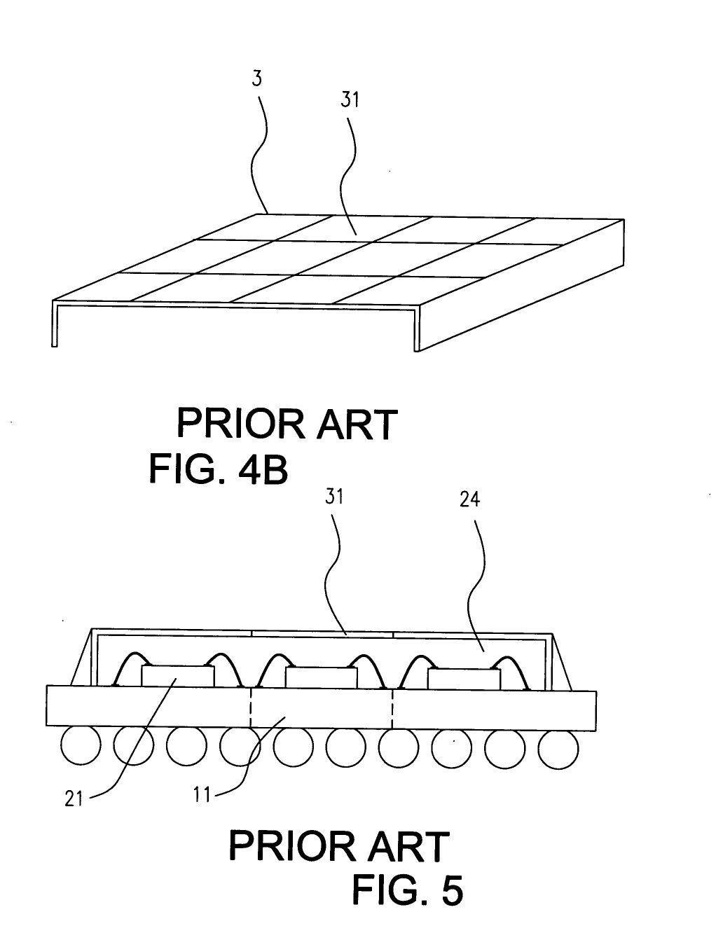

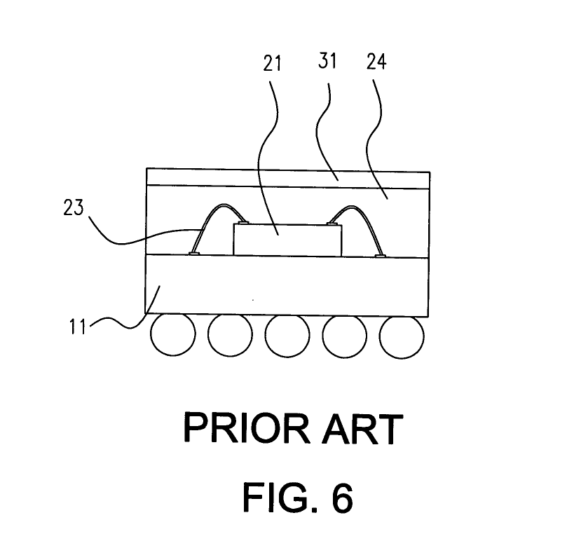

### DETAILED DESCRIPTION OF THE INVENTION

The thermal enhance package and a manufacturing method thereof according to the preferred embodiment of this invention will be described herein below with reference to the accompanying drawings, wherein the same reference numbers refer to the same elements.

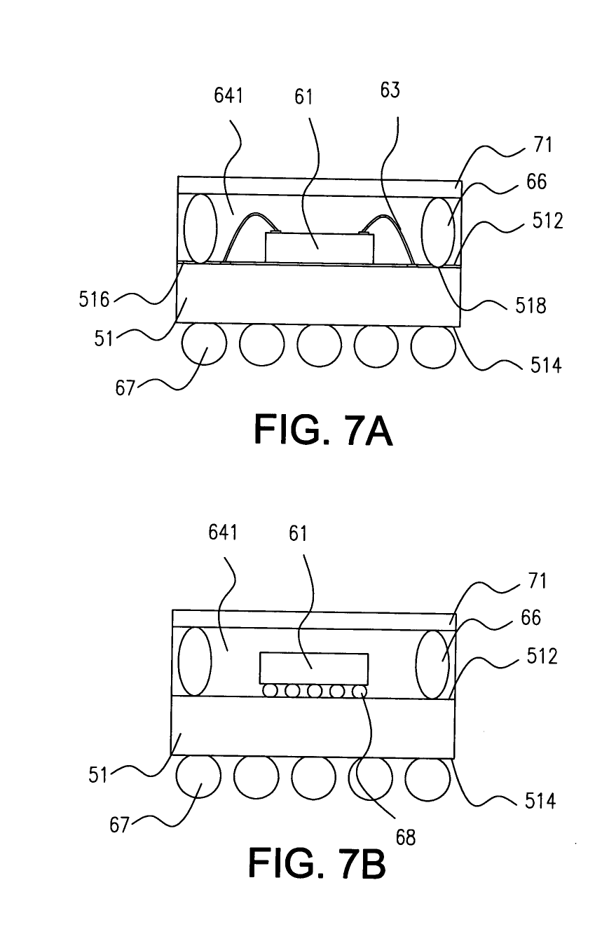

In accordance with a first preferred embodiment as shown in FIG. 7A, the thermal enhance package mainly comprises a substrate unit 51, a chip 61, a plurality of conductive wires 63, an encapsulation unit 64, a heat spreader unit 71 and a plurality of pellets 66. The substrate unit 51 has an upper surface 512 and a lower surface 514, and the chip 61 is disposed on the upper surface 512 of the substrate unit 51 and electrically connected to the substrate unit 51. Furthermore, the heat spreader unit 71 is disposed above the chip 61, and the pellets 66 are disposed on the upper surface 512 of the substrate unit 51 and connected to the heat spreader unit 71. And an encapsulation unit 64 encapsulates at least the pellets 66, the chip 61, the conductive wires 63, and the upper surface 512 of the substrate unit 51. Thus the heat arisen out of the chip 61 can be transmitted to the heat spreader unit 71 not only through the encapsulation unit 64 but also the pellets 66 and the substrate unit 51. Therein the pellets 66 can be conductive bumps, for example conductive adhesive body, conductive epoxy and metal bumps. Besides, as shown in FIG. 7B, a second embodiment is disclosed. Therein, the chip 61 is attached and electrically connected to the substrate unit via conductive pellets 68, for example solder bumps.

In addition, the material of the substrate unit 51 comprises organic. Namely, the substrate unit is an organic substrate unit. Thus a solder mask 516 is formed on the upper surface 512 of the substrate unit 51 and exposes at least one grounding contact 518 so as to connect to one of the pellets 66. Accordingly, the heat spreader unit 71 can be electrically connected to the substrate unit 71 so as to provide a good shielding and enhance the electrical performance of the package. Specifically, the pellets 66 can be conductive bumps, which comprise conductive adhesive bodies, conductive adhesive bodies with metal powder, and metal bumps. Moreover, a plurality of conductive devices 67, such as solder balls, are formed on the lower surface 514 of the substrate unit 51 so as to electrically connect to the external devices. Besides, a chromium layer is formed on the surface of the heat spreader unit 71 so as to prevent the surface of the heat spreader unit 71 from oxidation.

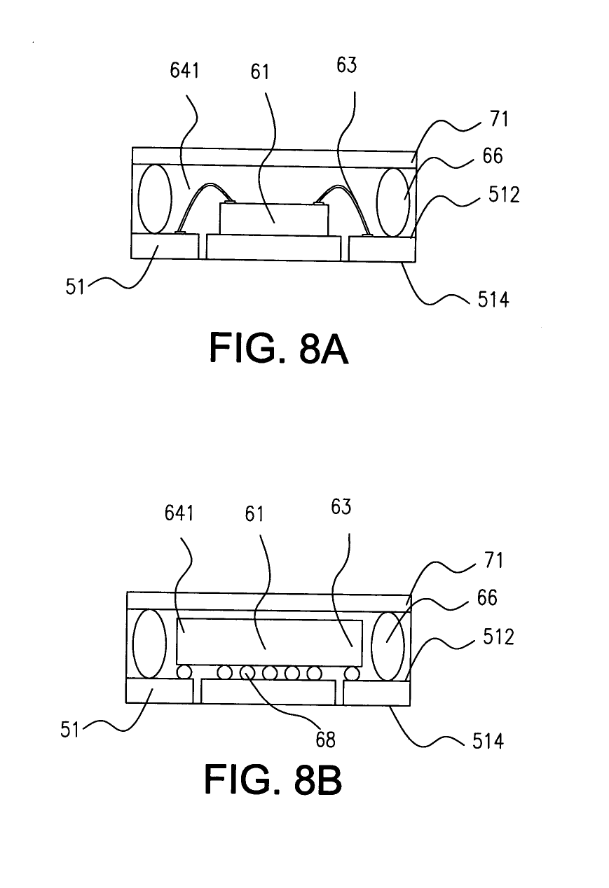

As mentioned above, the substrate unit 51 can be replaced with a lead frame unit. Namely, the thermal enhance package is a leadless package as shown in FIGS. 8A and 8B, which show a third and fourth embodiments respectively. It should be noted that the reference numeral of each element in FIGS. 8A and 8B corresponds to the same reference numeral of each element in FIGS. 7A and 7B.

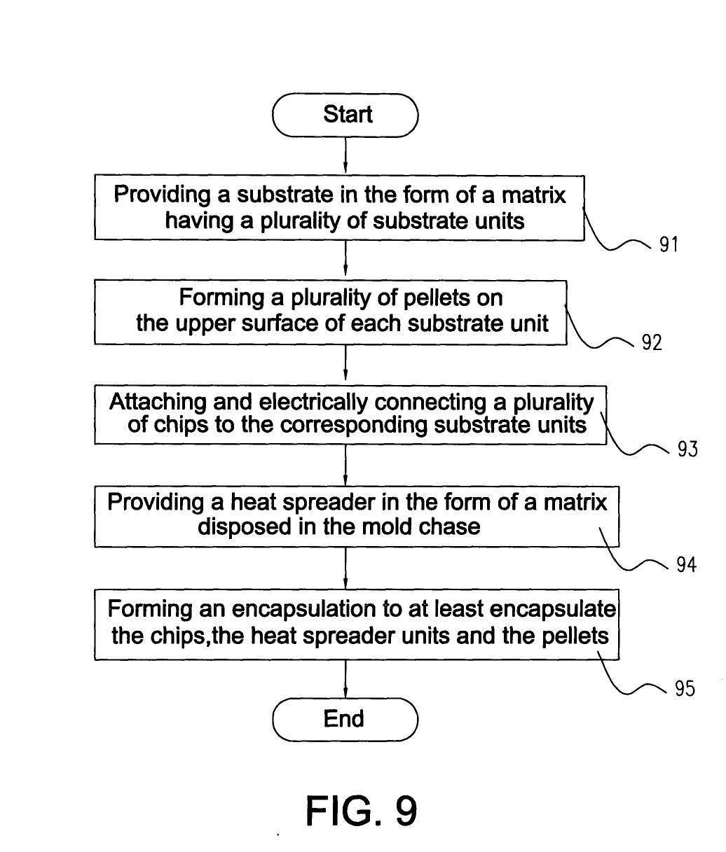

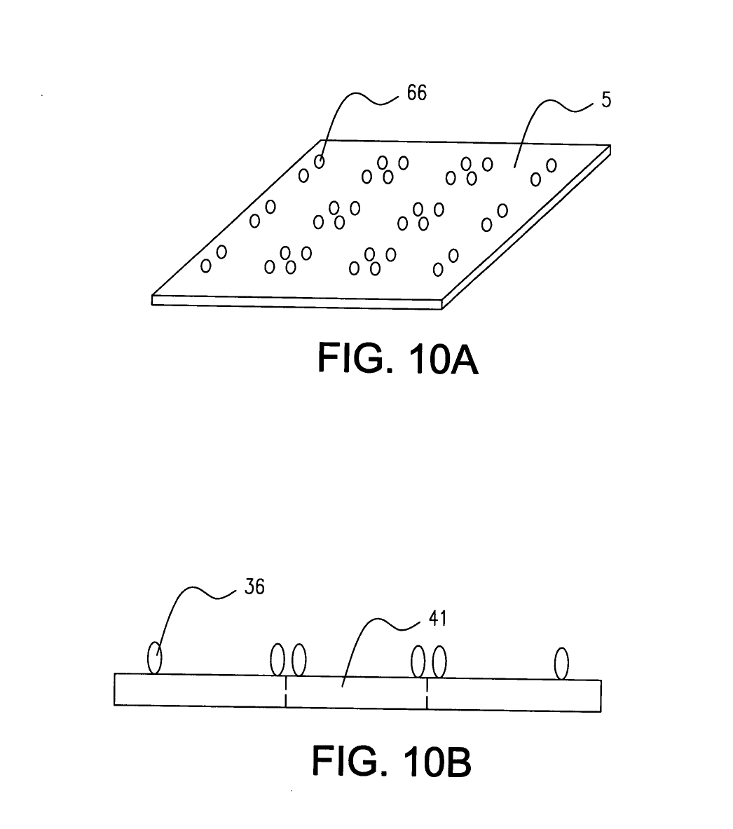

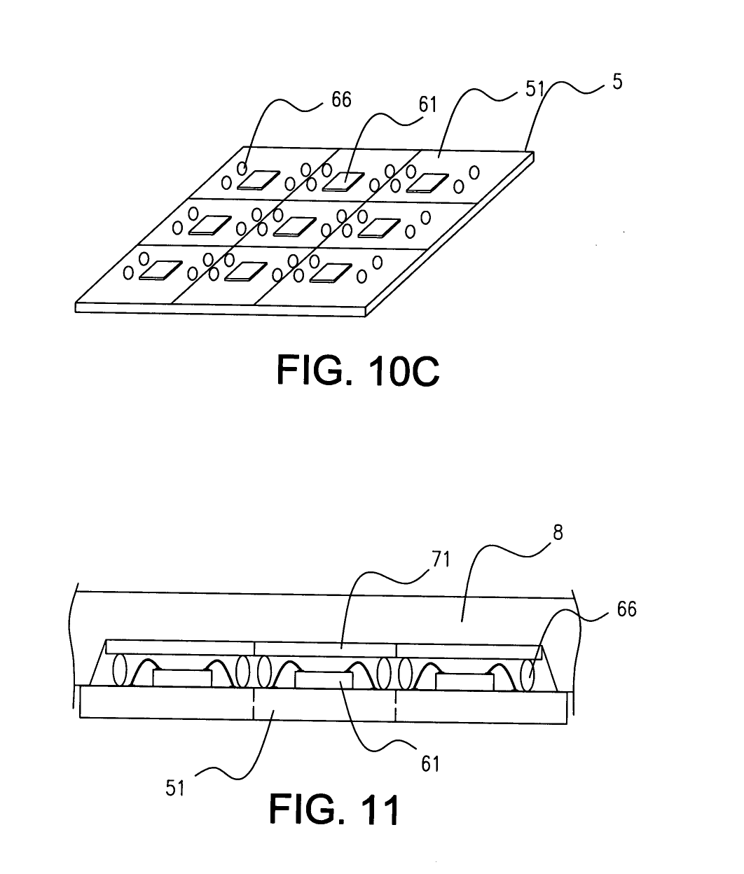

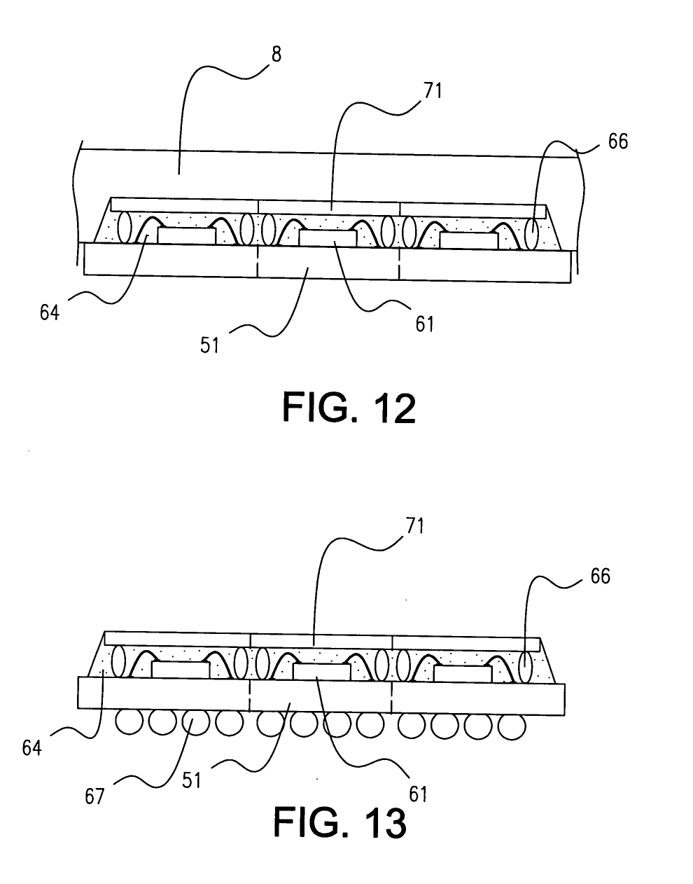

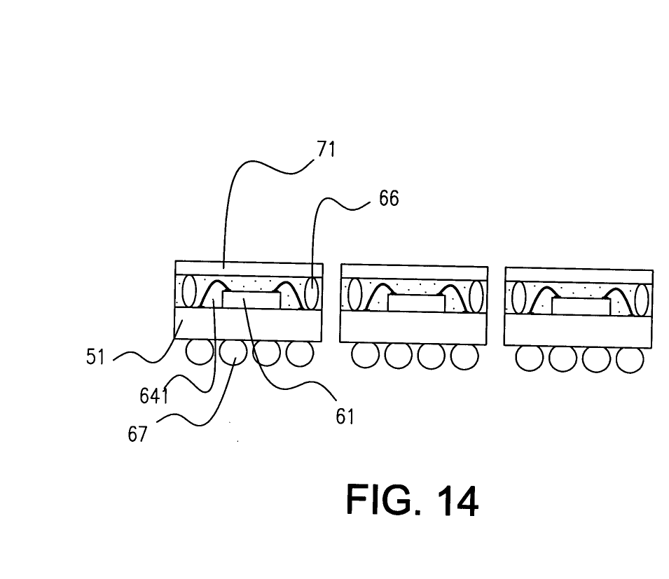

Next, referring to FIG. 9, a flow chart of a thermal enhance package manufacturing method is provided therein. Afterwards, referring to FIGS. 10A, 10B 10C and 11 to 14, which illustrate the process flow of a manufacturing method of the thermal enhance package of FIG. 7A. First, in step 91, a substrate 5 in the form of a matrix having a plurality of substrate units 51 is provided as shown in FIG. 10A. Next, in step 92, a plurality of pellets 66, are formed on the upper surface of each substrate unit 51 as shown in FIG. 10B. Afterwards, in step 93, a plurality of chips 61 are attached and electrically connected to the corresponding substrate units 51 by the method of wire bonding as shown in FIG. 10C. Then, in step 94, a heat spreader 7 in the form of a matrix is provided and disposed in the mold chase 8 as shown in FIG. 11, wherein the heat spreader 7 has a plurality of heat spreader units 71. Furthermore, in step 95, an encapsulation 64 at least encapsulates the chips 61 ,the heat spreader units 71 and the pellets so as to form the encapsulation 64 in the form of a matrix as shown in FIG. 13. Finally, a singulation process is performed to singulate the encapsulation 64 to from a plurality of thermal enhance packages as shown in FIG. 14. It should also be noted that the reference numeral of each element in FIGS. 10A, 10B, 10C, 11, 12, 13 and 14 corresponds to the same reference numeral of each element in FIG. 7A.

As mentioned above, we know that in each thermal enhance package, the pellets 66 connect the heat spreader unit 71 and the substrate unit 51 so that the heat arisen out of the chip 61 is transmitted to the heat spreader 71 not only through the encapsulation unit 641 but also through the pellets 66. In addition, the heat spreader unit 71 is electrically connected to the substrate unit 51 via the pellets 66 as a shielding as shown in FIG. 14. Thus the electrical performance of the thermal enhance package is enhanced and the shielding can prevent the effect of the magnetoelectricity from affecting the thermal enhance package.

Although the invention has been described in considerable detail with reference to certain preferred embodiments, it will be appreciated and understood that various changes and modifications may be made without departing from the spirit and scope of the invention as defined in the appended claims.

What is claimed is:

1. A thermal enhance package, comprising:
a substrate unit having an upper surface and a lower surface opposed to the upper surface;
a chip having an active surface and a back surface opposed to the active surface;
a plurality of conductive devices, the conductive devices electrically connecting the active surface of the chip and the upper surface of the substrate unit;
a plurality of pellets formed on the upper surface of the substrate unit and surrounding the chip; and
a heat spreader unit disposed above the chip and the pellets, wherein the heat spreader unit is connected to the pellets.

2. The thermal enhance package of claim 1, further comprising a plurality of solder balls formed on the lower surface of the substrate unit.

3. The thermal enhance package of claim 1, wherein the conductive devices comprise conductive bumps and the conductive bumps connects the chip and the substrate.

4. The thermal enhance package of claim 1, wherein the conductive devices comprises conductive wires and the back surface of the chip is attached on the upper surface of the substrate unit.

5. The thermal enhance package of claim 4, further comprising an encapsulation unit encapsulating the chip, the conductive wires, the pellets and the heat spreader unit.

6. The thermal enhance package of claim 1, wherein the pellets are thermally conductive bumps.

7. The thermal enhance package of claim 1, wherein the pellets are thermally conductive adhesive bodies.

8. The thermal enhance package of claim 7, wherein the thermally conductive adhesive bodies has metal powder therein.

9. The thermal enhance package of claim 1, wherein the pellets are electrically conductive bumps.

10. The thermal enhance package of claim 3, the conductive bumps are metal bumps.

11. The thermal enhance package of claim 3, the conductive bumps are electrically conductive adhesive bodies.

12. The thermal enhance package of claim 1, wherein a material of the substrate unit comprises organic, and a mask layer is formed on the upper surface of the substrate unit and exposes at least one grounding contact connecting to one of the pellets.

13. The thermal enhance package of claim 1, wherein the substrate unit is a lead frame.

14. The thermal enhance package of claim 13, wherein the lead frame is a lead-less lead frame.

15. The thermal enhance package of claim 1, wherein a chromium layer is formed on a surface of the heat spreader unit.

16. A thermal enhance package manufacturing method, comprising:
providing a substrate in the form of a matrix, wherein the substrate has a plurality of substrate units, and the substrate unit has an upper surface and a lower surface;
forming a plurality of pellets on the upper surface of each substrate unit;
providing a plurality of chips;
disposing each of the chips on each of the substrate units respectively;
electrically connecting each of the chips to each of the substrate units respectively;
providing a heat spreader in the form of a matrix having a plurality of heat spreader units;
attaching each of the heat spreader units to each of the substrate units respectively;
encapsulating the chips, the substrate and the heat spreader to form an encapsulation; and
singulating the encapsulation into the thermal enhance packages.

17. The thermal enhance package manufacturing method of claim 16, wherein a material of the substrate unit comprises organic, and a mask layer is formed on the upper surface of the substrate unit and exposes at least one grounding contact connecting to one of the pellets.

18. The thermal enhance package manufacturing method of claim 16, wherein a chromium layer is formed on a surface of the heat spreader.

19. The thermal enhance package manufacturing method of claim 16, further comprising a plurality of solder balls formed on the lower surface of the substrate unit.
